(19) United States
(12) Patent Application Publication
(10) Pub. No.: US 2025/0228140 A1
(43) Pub. Date: Jul. 10, 2025

(54) Dopants to Decrease BiSbX's and YBiPt's Bandgap for Optimal Current-In-Plane (CIP) Conductivity

(71) Applicant: Western Digital Technologies, Inc., San Jose, CA (US)

(72) Inventors: Quang LE, San Jose, CA (US); Brian R. YORK, San Jose, CA (US); Xiaoyong LIU, San Jose, CA (US); Son T. LE, San Jose, CA (US); Michael A. GRIBELYUK, Stamford, CT (US); Hisashi TAKANO, Fujisawa-shi, Kanagawa (JP)

(73) Assignee: Western Digital Technologies, Inc., San Jose, CA (US)

(21) Appl. No.: 19/011,136

(22) Filed: Jan. 6, 2025

Related U.S. Application Data
(60) Provisional application No. 63/676,743, filed on Jul. 29, 2024.
(60) Provisional application No. 63/625,616, filed on Jan. 26, 2024.
(60) Provisional application No. 63/619,447, filed on Jan. 10, 2024.

(51) Int. Cl. H10N 50/85; G11B 5/39; G11C 11/16; H03K 19/18; H10N 50/10

(52) U.S. Cl. CPC H10N 50/85; G11B 5/3909; G11C 11/161; H03K 19/18; H10N 50/10

(57) ABSTRACT

The present disclosure generally relates to topological semi-metal (TSM) and topological insulator (TI) based spin-orbit torque (SOT) devices and a method of forming thereof. TI or TSM-based SOT device (such as that with BiSb in the SOT layer) has been proposed for applications in magnetic switching and sensor applications, where current flows in a CIP (current-in-plane) or CPP (current-perpendicular-to-the-plane) direction, respectively. For CPP SOT devices, the requirement for the TI or TSM layer's bulk property is to be more insulating, to minimize shunting. However, for CIP SOT devices, the requirement for the TI or TSM layer's bulk property is to be more conductive, for less power consumption. Disclosed herein are various embodiments covering types and amounts of dopants for the TI or TSM layer, to decrease the bandgap of the TI or TSM layer for CIP SOT devices, thereby increasing the bulk conductivity for lower power consumption.

### CROSS-REFERENCE TO RELATED APPLICATIONS

This application claims benefit of U.S. provisional patent application Ser. Nos. 63/619,447, filed Jan. 10, 2024, 63/625,616, filed Jan. 26, 2024, and 63/676,743, filed Jul. 29, 2024, each of which is herein incorporated by reference.

### BACKGROUND OF THE DISCLOSURE

### Field of the Disclosure

Embodiments of the present disclosure generally relate to topological insulator (TI) based spin-orbit torque devices and a method of forming thereof.

### Description of the Related Art

BiSb layers are narrow band gap topological insulators with both giant spin Hall effect and high electrical conductivity. BiSb is a material that has been proposed in various spin-orbit torque (SOT) device applications, such as for a spin Hall layer for spintronic logic devices, magnetoresistive random access memory (MRAM) devices, sensors, magnetic recording read heads, and energy-assisted magnetic recording (EAMR) write heads.

However, utilizing BiSb materials in commercial SOT applications can present several obstacles. For example, BiSb materials have low melting points, large grain sizes, significant Sb migration issues upon thermal annealing due to its film roughness, difficulty maintaining a desired (012) or (001) orientation for maximum spin Hall effect, and are generally soft and easily damaged by ion milling. YBiPt is another topological insulator material that enables SOT applications. The requirements of the properties of the BiSb and YBiPt layers vary depending on the type of SOT device. For example, devices where current flows current-in-plane (CIP) have different property requirements than devices where current flows current-perpendicular-plane (CPP).

Therefore, there is a need for improved BiSb and YBiPt layers having various desired properties tailored to specific SOT devices.

### SUMMARY OF THE DISCLOSURE

The present disclosure generally relates to topological semi-metal (TSM) or topological insulator (TI) based spin-orbit torque (SOT) devices and a method of forming thereof. TI or TSM-based SOT device (such as that with BiSb or YBiPt in the SOT layer) has been proposed for applications in magnetic switching and sensor applications, where current flows in a CIP (current-in-plane) or CPP (current-perpendicular-to-the-plane) direction, respectively. For CPP SOT devices, the requirement for the TI or TSM layer's bulk property is to be more insulating, to minimize shunting. However, for CIP SOT devices, the requirement for the TI or TSM layer's bulk property is to be more conductive, for less power consumption. Disclosed herein are various embodiments covering types and amounts of dopants for the TI or TSM layer, to decrease the bandgap of the TI or TSM layer for CIP SOT devices, thereby increasing the bulk conductivity for lower power consumption.

In one embodiment, a current-in-plane (CIP) spin orbit torque (SOT) device comprises a buffer layer, a doped bismuth antimony (BiSb) layer over the buffer layer, the doped BiSb layer comprising BiSb and a Ge—TiO, Ge-VO, or X-N dopant for controlling a bandgap of the BiSb layer, wherein the X-N dopant comprises N and X is one or more of elements selected from the group consisting of: Sc, Ti, V, Cr, Zr, Nb, Mo, Hf, Ta, W, Cu, Rh, Ir, Pd, Pt, B, Al, Ga, In, Si, Ge, Sn, As, S, Se, Te, and alloy combinations thereof, such as CuN, GeN, or GeWN, and increasing Sb percentage, an interlayer over the BiSb layer, and a ferromagnetic layer over the interlayer.

In another embodiment, a current-in-plane (CIP) spin orbit torque (SOT) device comprises a buffer layer, a doped yttrium bismuth platinum (YBiPt) layer over the buffer layer, the doped YBiPt layer comprising YBiPt and a X-N dopant, a X-C dopant, or a X-O dopant, where X is one or more of elements selected from the group consisting of: Sc, Ti, V, Cr, Zr, Nb, Mo, Hf, Ta, W, Cu, Rh, Ir, Pd, Pt, B, Al, Ga, In, Si, Ge, Sn, As, S, Se, Te, and alloy combinations thereof, such as Ge—TiO, and increasing Sb percentage, an interlayer over the BiSb layer, and a ferromagnetic layer over the interlayer.

In yet another embodiment, a current-in-plane (CIP) spin orbit torque (SOT) device comprises a buffer layer, a doped bismuth antimony (BiSb) layer over the buffer layer, the doped BiSb layer comprising BiSb and a dopant for controlling a bandgap of the BiSb layer, wherein the dopant is one or more of elements selected from the group consisting of: B, Al, Ga, In, N, C, Si, Ge, Sn, P, As, Ni, Cu, Zn, Mg, Zr, Nb, Mo, Ta, Hf, W, Pt, Ir, Ge—TiO, GeN, GeWN, and alloy dopant combinations thereof, such as Ge—TiO, CuN, GeN, or GeWN, and increasing Sb percentage, an interlayer over the BiSb layer, and a ferromagnetic layer over the interlayer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic illustration of certain embodiments of a magnetic media drive including a write head having a SOT MTJ device.

FIG. 2 is a fragmented, cross-sectional side view of certain embodiments of a read/write head having a SOT MTJ device.

FIG. 3A illustrates a spin orbit torque (SOT) device, according to one embodiment.

FIG. 3B illustrates a SOT device, according to another embodiment.

FIG. 4A illustrates a current-in-plane (CIP) SOT device, according to one embodiment.

FIG. 4B illustrates a current-perpendicular-plane (CPP) SOT device, according to another embodiment.

FIG. 5A illustrates a graph of conductivity (i.e., the inverse of resistivity (ρ) (1/ρ)×1000) of the BiSbX (where X is a dopant) versus thickness of various BiSbX layers in Å, according to one embodiment.

FIG. 5B illustrates a graph of conductivity (i.e., the inverse of resistivity (ρ) (1/ρ)×1000) of the BiSbX (where X is Ge-TiO at 8 at. % dopant) versus thickness of various BiSbX (where X is GE-TiO at 8 at. % dopant) in Å, that increase the bulk conductivity and decrease the bandgap compared to undoped BiSb and BiSbX (where X is TiO at 8 at. % dopant) according to one embodiment.

FIG. 5C illustrates a graph of conductivity (i.e., the inverse of resistivity (ρ) (1/ρ)×1000) of the BiSby (where Y is at different at. %) versus thickness of BiSb_{Y} (where Y is at different at. %) in Å that increase the bulk conductivity and lowering the bandgap, according to one embodiment.

FIG. 6A is a schematic cross-sectional view of a SOT device for use in a MAMR write head, such as the MAMR write head of the drive of FIG. 1 or other suitable magnetic media drives.

FIGS. 6B-6C are schematic MFS views of certain embodiments of a portion of a MAMR write head with a SOT device of FIG. 6A.

FIG. 7 is a schematic cross-sectional view of a SOT MTJ used as a MRAM device.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

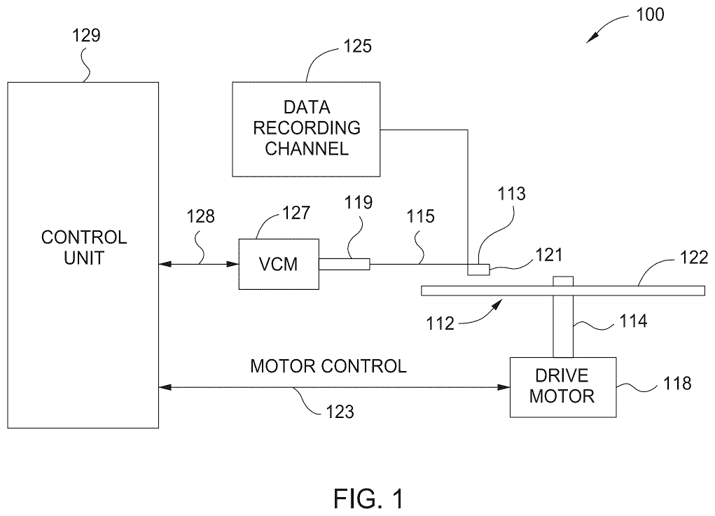

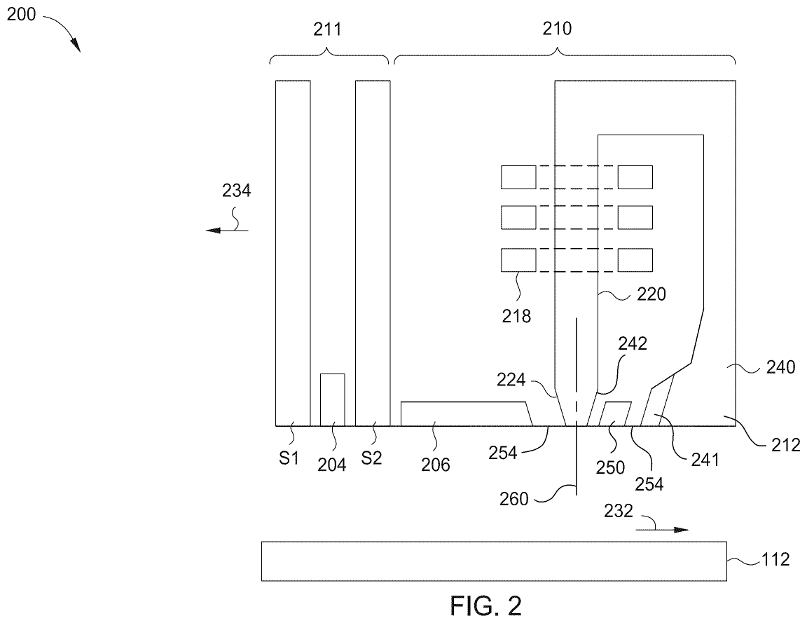

The various SOT devices may be fabricated with the disclosed dopants in the TI materials for bandgap tuning, based on various end applications according to several embodiments. CIP SOT devices may be used in magnetic recording devices such as a recording write head shown in FIG. 2, respectively, and specifically a MAMR write head in FIGS. 7A-7B, which may be used in a hard disk drive (HDD) shown in FIG. 1. CIP SOT devices may also be used in an Magneto-resistive Random Access Memory (MRAM), an example memory cell with an SOT layer is disclosed in FIG. 7. Additionally, CIP SOT devices may be used in artificial intelligence chip/processor applications, e.g., as part of spintronic based logic devices that rely on spintronic properties to encode, compute and transmit logic states. CPP SOT devices may be used in sensor applications, in particular as part of the sensing mechanism for a magnetic recording head's reader such as that shown in FIG. 2, e.g., within an HDD shown in FIG. 1 or other magnetic recording devices like tape drive. CPP SOT devices may be used more generally in other magnetic sensing applications outside of magnetic recording.

FIG. 1 is a schematic illustration of certain embodiments of a magnetic media drive 100 including a write head having a SOT MTJ device. Such a magnetic media drive may be a single drive or comprise multiple drives. For the sake of illustration, a single disk drive 100 is shown according to certain embodiments. As shown, at least one rotatable magnetic disk 112 is supported on a spindle 114 and rotated by a drive motor 118. The magnetic recording on each magnetic disk 112 is in the form of any suitable patterns of data tracks, such as annular patterns of concentric data tracks (not shown) on the magnetic disk 112.

At least one slider 113 is positioned near the magnetic disk 112, each slider 113 supporting one or more magnetic head assemblies 121 that include a SOT device. As the magnetic disk 112 rotates, the slider 113 moves radially in and out over the disk surface 122 so that the magnetic head assembly 121 may access different tracks of the magnetic disk 112 where desired data are written. Each slider 113 is attached to an actuator arm 119 by way of a suspension 115. The suspension 115 provides a slight spring force which biases the slider 113 toward the disk surface 122. Each actuator arm 119 is attached to an actuator means 127. The actuator means 127 as shown in FIG. 2 may be a voice coil motor (VCM). The VCM includes a coil movable within a fixed magnetic field, the direction and speed of the coil movements being controlled by the motor current signals supplied by control unit 129.

During operation of the disk drive 100, the rotation of the magnetic disk 112 generates an air bearing between the slider 113 and the disk surface 122 which exerts an upward force or lift on the slider 113. The air bearing thus counter-balances the slight spring force of suspension 115 and supports slider 113 off and slightly above the disk surface 122 by a small, substantially constant spacing during normal operation.

The various components of the disk drive 100 are controlled in operation by control signals generated by control unit 129, such as access control signals and internal clock signals. Typically, the control unit 129 comprises logic control circuits, storage means and a microprocessor. The control unit 129 generates control signals to control various system operations such as drive motor control signals on line 123 and head position and seek control signals on line 128. The control signals on line 128 provide the desired current profiles to optimally move and position slider 113 to the desired data track on disk 112. Write and read signals are communicated to and from write and read heads on the assembly 121 by way of recording channel 125.

The above description of a typical magnetic media drive and the accompanying illustration of FIG. 1 are for representation purposes only. It should be apparent that magnetic media drives may contain a large number of media, or disks, and actuators, and each actuator may support a number of sliders.

FIG. 2 is a fragmented, cross-sectional side view of certain embodiments of a read/write head 200 having a SOT device. The read/write head 200 faces a magnetic media 112. The read/write head 200 may correspond to the magnetic head assembly 121 described in FIG. 1. The read/write head 200 includes a media facing surface (MFS) 212, such as a gas bearing surface, facing the disk 112, a write head 210, and a magnetic read head 211. As shown in FIG. 2, the magnetic media 112 moves past the write head 210 in the direction indicated by the arrow 232 and the read/write head 200 moves in the direction indicated by the arrow 234.

In some embodiments, the magnetic read head 211 is a magnetoresistive (MR) read head that includes an MR sensing element 204 located between MR shields S1 and S2. In other embodiments, the magnetic read head 211 is a magnetic tunnel junction (MTJ) read head that includes a MTJ sensing device 204 located between MR shields S1 and S2. The magnetic fields of the adjacent magnetized regions in the magnetic disk 112 are detectable by the MR (or MTJ) sensing element 204 as the recorded bits. The SOT device of various embodiments can be incorporated into the read head 211 as the sensing element. An example of an SOT read head is described in co-pending patent application titled “Topological Insulator Based Spin Torque Oscillator Reader,” U.S. application Ser. No. 17/828,226, filed May 31, 2022, assigned to the same assignee of this application, which is herein incorporated by reference.

The write head 210 includes a main pole 220, a leading shield 206, a trailing shield 240, an optional spin orbital torque (SOT) device 250, and a coil 218 that excites the main pole 220. The coil 218 may have a “pancake” structure which winds around a back-contact between the main pole 220 and the trailing shield 240, instead of a “helical” structure shown in FIG. 2. When included, e.g., to achieve a Microwave Assisted Magnetic Recording (MAMR) effect, the SOT device 250 is formed in a gap 254 between the main pole 220 and the trailing shield 240. The main pole 220 includes a trailing taper 242 and a leading taper 244. The trailing taper 242 extends from a location recessed from the MFS 212 to the MFS 212. The leading taper 244 extends from a location recessed from the MFS 212 to the MFS 212. The trailing taper 242 and the leading taper 244 may have the same degree of taper, and the degree of taper is measured with respect to a longitudinal axis 260 of the main pole 220. In some embodiments, the main pole 220 does not include the trailing taper 242 and the leading taper 244. Instead, the main pole 220 includes a trailing side (not shown) and a leading side (not shown), and the trailing side and the leading side are substantially parallel. The main pole 220 may be a magnetic material, such as a FeCo alloy. The leading shield 206 and the trailing shield 240 may be a magnetic material, such as a NiFe alloy. In certain embodiments, the trailing shield 240 can include a trailing shield hot buffer layer 241. The trailing shield hot buffer layer 241 can include a high moment sputter material, such as CoFeN, FeXN, or FeX, where X includes at least one of N, Al, Ni, Co, Ta, Re, Ir, Pt, Rh, Ta, Zr, and Ti. In certain embodiments, the trailing shield 240 does not include a trailing shield hot buffer layer.

Dopant options for lowering the bandgap for the SOT material are further described below. A bandgap is an energy range where no electronic states can exist, and defines the energy needed to move an electron from the valence band to the conduction band. Once moved, the electron in the conduction band and the hole it vacated in the valence band become charge carriers. Thus, the size of the bandgap of a material directly affects its conductivity. Increasing the carrier concentration will generally increase the conduction in a semiconductor. This can happen through doping with n-type or p-type elemental dopants contributing more electron or hole carriers, or by changing the carrier mobility of either electrons or holes. Generally, dopants such as O, S, Se, F, Cl, and Br (selected from Groups 16-17 in the periodic table) are consider n-type dopants (donors) for BiSb, and dopants such as B, Al, Ga, In, C, Si, Ge, and Sn (selected from Groups 13-14 in the periodic table) are considered p-type dopants (acceptors). Donor dopants generally considered to increase the conductivity of semiconductors. As such, donor or n-type dopants such as O, S, Se, F, Cl, and Br may be selected to lower the band gap, while p-type dopants such as B, Al, Ga, In, C, Si, Ge, and Sn may be selected to increase the carrier concentration, in addition to lowering the band gap. Note in this disclosure when doping is mentioned, different options for doping can be pursued, including co-sputtering and lamination.

However, because of the valence plurality, elements like N, P, and As (which are from Group 15 in the periodic element table, same as Bi and Sb) can also be used as dopants for BiSb in BiSb layers. In fact, N-doping of oxides like ZnO and CuAlO₂ can be used to increase the conductivity of such oxides by lowering the band gap. Higher N-doping produces smaller band gaps. Molecular N₂ doping is considered n-type doping and atomic N is considered p-type doping.

Moreover, Ge—TiO, Ge-VO, and nitrides of Ge, Cu, and GeW have been shown to also increase the bulk conduction by lowering the band gap. Similarly, other X—N nitride dopants, such as the higher nitrogen affinity elements, where X=Sc, Ti, V, Cr, Zr, Nb, Mo, Hf, Ta, or W, as well as the noble metal nitrides, such as RhN, IrN, PdN, and PtN, or SiN, InN, AsN, SeN, and TeN, or in any alloy combinations of the above elements thereof may also lower the band gap and increase the conductivity of BiSbX layers. Doping with +2 valence elements like Zn and Mg may help increase acceptor concentration. Dopants like Zr and Ir may likewise help increase acceptor concentration as well while also increasing melting temp.

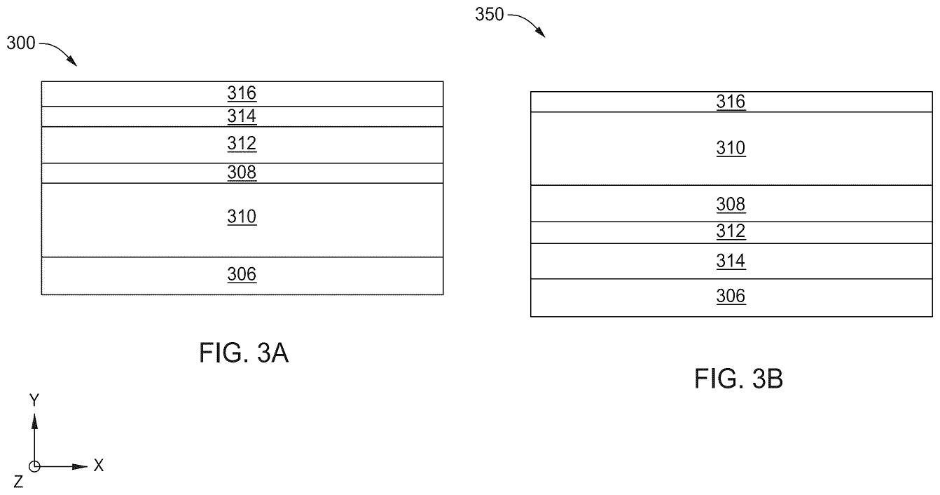

FIG. 3A illustrates a spin orbit torque (SOT) device 300, according to one embodiment. The SOT device 300 comprises a buffer layer 306, which may be disposed over a first shield, a seed layer, or substrate (depending on end application, not shown) and/or an insulation layer (not shown), a spin Hall effect (SHE) layer or BiSb layer 310 (which may also be referred to herein as a topological insulator (TI) layer 310 or a topological semi-metal (TSM) layer 310) disposed on the buffer layer 306, a first interlayer (interlayer1) 308 disposed on the SHE layer 310, a ferromagnetic (FM) layer 312 disposed on the interlayer1 308, a second interlayer (interlayer2) 314 disposed on the FM layer 312, and a cap layer 316 disposed on the interlayer2 314. A second shield or substrate (not shown) and/or an insulation layer (depending on end application, not shown) may be disposed over the cap layer 316.

FIG. 3B illustrates a SOT device 350, according to another embodiment. The SOT device 350 comprises a buffer layer 306, which may be disposed over a first shield or substrate (depending on end application, not shown) and/or an insulation layer (not shown), a interlayer2 314 disposed on the buffer layer 306, a ferromagnetic (FM) layer 312 disposed on the interlayer2 314, an interlayer1 308 disposed on the FM layer 312, a spin Hall effect (SHE) layer or TI or TSM layer 310 disposed on the interlayer1 308, and a cap layer 316 disposed on the SHE layer 310. A second shield or substrate (depending on end application, not shown) and/or an insulation layer (not shown) may be disposed over the cap layer 316.

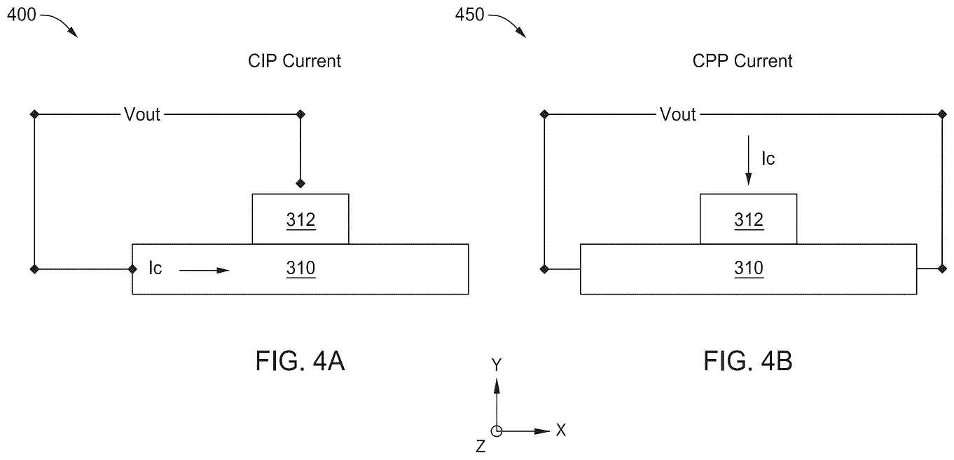

In both SOT devices 300, 350, the TI layer 310 may comprise a doped TI material such as bismuth antimony (BiSb) of various thicknesses, as discussed further below. For example, the BiSb layer may be doped with GeN, GeWN, Ge—TiO, Ge-VO, or CuN. When the BiSb layer is doped with Ge—TiO, the Ti/O ratio is less than 1. The dopants and the thickness of the TI layer 310 are selected during fabrication based on the level of bulk conductivity desired, as further explained in FIGS. 4A-6. In embodiments where the TI layer 310 is doped, the interlayer1 308, the buffer layer 306, and/or the cap layer 316 may be doped as well. The TI layer 310 may have a (012) crystal orientation or a (001) crystal orientation. The TI layer 310 may have a thickness in the y-direction of about 50 Å to about 600 Å. It is noted that the various SHE and TI layers in the figures of this disclosure may also comprise YBiPt instead of BiSb. For brevity, BiSb may be used in the description but the embodiments are not limited to that material.

The TSM layer 310 may comprise a doped YBiPt layer comprising YBiPt and a metal X-N dopant, where X is a higher nitrogen affinity elements of Sc, Ti, V, Cr, Zr, Nb, Mo, Hf, Ta, or W; the noble metal nitrides of Cu, Rh, Ir, Pd, and Pt; and the nitrides from groups 13 and higher in the periodic table such as B, Al, Ga, In, Si, Ge, Sn, As, S, Se, and Te; and alloy combinations thereof. Since YBiPt has elements from various groups of the periodic table, band gap alteration may also be possible with X-C or X-O dopants to either increase or decrease the band gap, where X is any element referenced in this paragraph including the prior listing of higher nitrogen affinity elements of X, as well as the elements forming nitrides listed above.

In some embodiments, YBiPt can be doped with X, where X is a rare earth element in the Lanthanide series, ranging from Gd (element 64) through Lu (element 71). These dopants have been found to not change the structure of YBiPt from its cF12—space group (SG) 216 structure. Similarly, X could also be one of Sn, Sb, Ni, GeN, GeWN, and Pd with little or no change to the structure, as these elements would form in YPtX, BiPtX, or YBiX. Given there are a large number of phases (cF12—SG 216 phase) with Hf, Zr, Ti, and V and one of the Y, Pt, or Bi elements, X may also be Hf, Zr, Ti, and V without affecting structure. In addition, X can also be Co or Ir. In sum, there is a class of dopants that don't change the structure for YBiPt, including the Lanthanide series rare earths Gd through Lu; Sn, Sb, Ni, and Pd; Hf, Zr, Ti and V; and Co and Ir.

The cap layer 316 may comprise nonmagnetic, high resistivity materials, such as: thin ceramic oxides or nitrides of TiN, SiN, MgTiO, and MgO; amorphous/nanocrystalline metals such as NifeGe, NiFeTa, NiTa, NiHf, NiFeHf, CoHf, CoFeHf, NiWTa, NiFeW, NiW, WRe, beta-Ta, and beta-W; or nitrides, oxides, or borides of above-mentioned elements, compounds, and/or alloys such as NiTaN, NiFeTaN, NiWTaN, NiWN, WReN, TaN, WN, TaOx, WOx, WB, HfB, NiHfB, NiFeHfB, CoHfB, and CoFeHfB, where x is a numeral. In some embodiments, lower atomic number (Z) materials are preferred in the cap layer 316 to reduce sputter intermixing with the FM layer 312, but high Z alloys can be used, if used in combination with a migration barrier beneath, or if the high Z elements are used with a high resistive oxide, nitride, or boride. The cap layer 316 can comprise multilayer combinations of the above-mentioned materials, and the overall thickness of the cap layer 316 in the y-direction is less than or equal to about 100 Å (nominally about 15 Å to about 50 Å).

The FM layer 312, which may serve as a part of the interlayer2 314, has a thickness of about 5 Å to about 15 Å in the y-direction, and may comprise NiFe, CoFe, NiFeX, CoFeX, Fex, Cox, or Nix, where X is one or more of the following elements: Co, Ni, Cu, Si, Al, Mn, Ge, Cr, Ta, Hf, W, Re, Pt, Ir, N, and B. The FM layer 312 may comprise any magnetic layer combination or alloy combination of these elements that can yield a low coercivity, negative (or near zero) magnetostrictive FM layer 312 or in multilayer combinations with other higher polarizing materials like Heusler alloys or high Ni containing alloy FM layers.

The SOT devices 300, 350 may be textured amorphous/nanocrystalline stacks or epitaxial stacks. When the SOT devices 300, 350 are textured amorphous/nanocrystalline stacks, the buffer layer 306 (and/or the seed layer if included) may comprise high resistance nonmagnetic amorphous/nanocrystalline material with nearest-neighbor diffraction peak 2.0 Å to about 2.5 Å or face-centered cubic (fcc) crystalline/nanocrystalline seed with an a-axis of about 3.5 Å to about 4.0 Å, such as NiX, NiFeX, Cox, CoFeX, and CuX, where, for example, X is one or more of the following elements: Cr, Co, Fe, Ni, Cu, Ta, W, Hf, N, B, Ge, Si, Al, Re, Pt, Ir, Mo, Zr, Nb, or alloy combinations thereof. The buffer layer 306 may be a bilayer or a multilayer structure comprising high resistance insulating layers (crystalline or nanocrystalline), for example, NiFeGe/MgO/NiAlGe, NiFeCr/Cu, NiFeCr/NiCu, or other insulators like AlN, SiN, etc.

When the SOT devices 300, 350 are textured amorphous/nanocrystalline stacks, the interlayer1 308 and the interlayer2 314 may each individually comprise a single layer or a multilayer structure of high resistance nonmagnetic amorphous/nanocrystalline material with nearest-neighbor diffraction peak 2.0 Å to about 2.5 Å or fcc crystalline/nanocrystalline seed with an a-axis of about 3.5 Å to about 4.0 Å, such as NiX, NiFeX, CoX, CoFeX, and CuX, where, for example, X is one or more of the following elements: Cr, Co, Fe, Ni, Cu, Ta, W, Hf, N, B, Ge, Si, Al, Re, Pt, Ir, Mo, Zr, Nb, or alloy combinations thereof, or a multilayer structure comprising a high spin transparent and/or higher resistive layer next to the FM layer 312, such as NiO, MgOx, MgTiO, TiO, where X is a numeral greater than or equal to 1.

When the SOT devices 300, 350 are epitaxial stacks, the seed layer may comprise high resistance nonmagnetic amorphous/nanocrystalline material with nearest-neighbor diffraction peak 2.0 Å to about 2.5 Å or fcc crystalline/nanocrystalline seed with an a-axis of about 3.5 Å to about 4.0 Å, such as NiX, NiFeX, Cox, CoFeX, and CuX, where, for example, X is one or more of the following elements: Cr, Co, Fe, Ni, Cu, Ta, W, Hf, N, B, Ge, Si, Al, Re, Pt, Ir, Mo, Zr, Nb, or alloy combinations thereof. The buffer layer 306 may comprise one or more texturing layers (not shown) which may be deposited on a heated substrate or seed layer, the texturing layer(s) comprising a nonmagnetic amorphous/nanocrystalline structure breaking layer like NiFeTa, CoFeTa, or a crystalline fcc layer like MgO, MgTiO with a nonmagnetic texturing layer of Al-X alloy where X is one of more of Fe, Co, Ni, Ru, Rh, and Ir, or the textured layer may be deposited as a heated film (>250° C.) and comprise Cr or CrX alloys where X is one or more of Mo, Mn, Ru, Ti, and W, for example.

When the SOT devices 300, 350 are epitaxial stacks, the buffer layer 306 may comprise (1) high resistance crystalline fcc materials like MgO, TiO, and VO, (2) nitrides and carbides of Sc, Ti, V, Cr, Zr, Nb, Ta, Hf, and W, (3) B2 or bcc materials like NiAl, RuAl, RhAl, etc., or (4) X-Al binary alloys, where X=Fe, Co, Ni, Ru, Rh, Ir, etc. The interlayer1 308 may be a single layer or a multilayer structure comprising a high resistance layer like that in the buffer layer 306 in combination with a high spin polarizing layer magnetic or non-magnetic Heusler alloy or half Heusler alloy. Examples of high spin polarizing layer magnetic or non-magnetic Heusler alloys or half Heusler alloys may be found in co-pending patent application titled “Spin-Orbit Torque Reader with Recessed Spin Hall Effect Layer,” U.S. application Ser. No. 18/368,220, filed Sep. 14, 2023, assigned to the same assignee of this application, which is herein incorporated by reference. The interlayer2 314 may be a single layer or a multilayer structure comprising a crystalline high resistance layer like that in the buffer layer 306 in combination with any other high resistance layer, such as a crystalline or amorphous/nanocrystalline layer like AlN or SiN, or any high resistance amorphous or nanocrystalline layer like NiFeGe or NiAlGe. The cap layer 316 may comprise any high resistance material crystalline or amorphous/nanocrystalline.

FIG. 4A illustrates a current-in-plane (CIP) SOT device 400, according to one embodiment. The CIP SOT device 400 may be used in combination with the SOT device 300 of FIG. 3A and/or the SOT device 350 of FIG. 3B. The SOT device 400 comprises a TI or TSM layer 310 and the FM layer 312 disposed over the TI or TSM layer 310. While the FM layer 312 is disposed over the TI or TSM layer 310, the TI or TSM layer 310 may be disposed over the FM layer 312 instead. The SOT device 400 may comprise additional layers not shown, such as a buffer layer 306, an interlayer1 308, an interlayer2 314, and/or a cap layer 316, as discussed above in FIGS. 3A-3B.

During operation, current (Ic) is applied to the TI or TSM layer 310 in the x-direction, or in-plane with the TI or TSM layer 310. Due to the spin Hall effect, a spin current is generated and flows perpendicularly into the FM layer 312, causing the FM layer 312 to rotate or switch, which can be detected by measuring the voltage read out (Vout) based on an anomalous Hall effect or tunnel magnetoresistance (TMR) with an optional tunnel barrier layer (not shown) and a top pinned FM layer(s) (not shown). Such CIP SOT devices 400 have fast magnetic switching of the FM layer 312, and generally require the bulk conductivity property of the TI or TSM layer 310 to be high for less power consumption during operation. For example, the CIP SOT device 400 may be used in memory applications, such as SOT MRAM, HDD write heads, such as the write head 210 of FIG. 2, and SOT-based logic devices, including artificial intelligence (AI) chips.

FIG. 4B illustrates a current-perpendicular-plane (CPP) SOT device 450, according to another embodiment. The CPP SOT device 450 may be used in combination with the SOT device 300 of FIG. 3A and/or the SOT device 350 of FIG. 3B. The SOT device 450 comprises a TI or TSM layer 310 and the FM layer 312 disposed over the TI or TSM layer 310. While the FM layer 312 is disposed over the TI or TSM layer 310, the TI or TSM layer 310 may be disposed over the FM layer 312 instead. The SOT device 450 may comprise additional layers not shown, such as a buffer layer 306, an interlayer1 308, an interlayer2 314, and/or a cap layer 316, as discussed above.

During operation, current (Ic) is applied to the top of the FM layer 312 in the-y-direction, or perpendicular to the plane of the TI or TSM layer 310. The output voltage (Vout) is read in-plane of the TI or TSM layer 310 based on the inverse spin Hall effect (iSHE). Such CPP SOT devices 450 generally require the bulk conductivity property of the TI or TSM layer 310 to be lower and more insulating to minimize shunting during signal read out. For example, the CPP SOT device 450 may be used in read heads, such as the read head 211 of FIG. 2.

As mentioned above, in both SOT devices 400 and 450, the TI or TSM layer 310 may comprise doped bismuth antimony (BiSb) of various thicknesses, as discussed further below. As such, the TI or TSM layer 310 may be referred to herein as a BiSb layer 310. The dopants and the thickness of the BiSb layer 310 are selected during fabrication based on the level of bulk conductivity desired. In the CIP SOT device 400, the amount of conductivity selected is about 1.5×10⁵ ohm⁻¹m⁻¹ or above, and in the CPP SOT device 450, the amount of conductivity selected is about 1.0×10⁵ ohm⁻¹m⁻¹ or below.

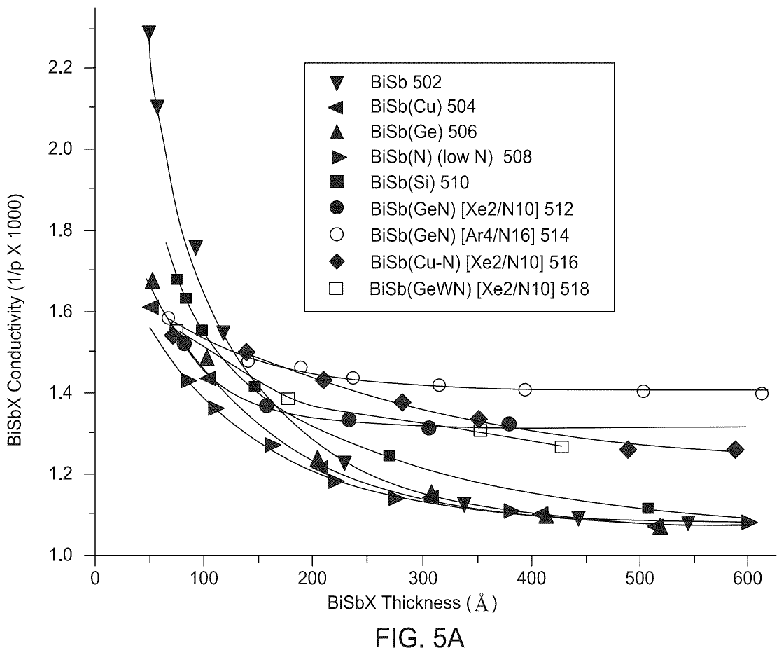

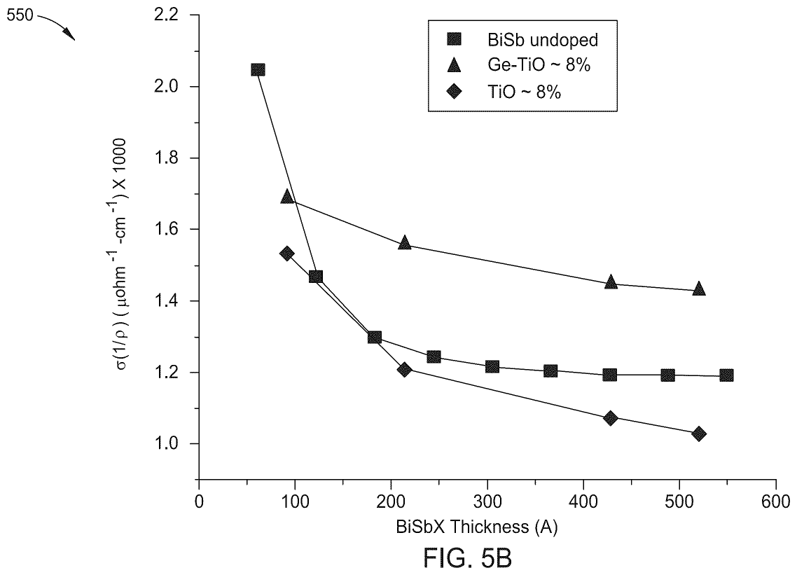

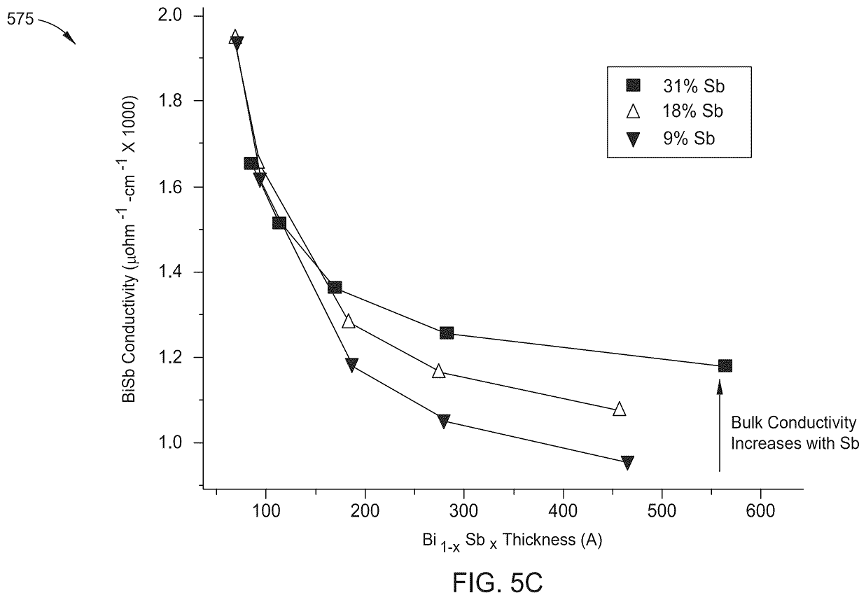

FIG. 5A illustrates a graph 500 of total film conductivity (i.e., the inverse of resistivity (ρ) (1/ρ)×1000) of the BiSbX (where X is a dopant) versus thickness of various BiSbX layers in A, according to one embodiment. FIG. 5B illustrates a graph 550 of conductivity (i.e., the inverse of resistivity (ρ) (1/ρ)×1000) of the BiSbX (where X is Ge—TiO at 8 at. % dopant) versus thickness of various BiSbX (where X is Ge—TiO at 8 at. % dopant and the Ti/O ratio is less than 1) in Å, that increase the bulk conductivity and decrease the bandgap compared to undoped BiSb and BiSbX (where X is TiO at 8 at. % dopant) according to one embodiment. FIG. 5C illustrates a graph 575 of conductivity (i.e., the inverse of resistivity (ρ) (1/ρ)×1000) of the BiSby (where Y is at different at. %) versus thickness of BiSby (where Y is at different at. %) in Å, that increase the bulk conductivity and lowering the bandgap, according to another embodiment. Each of the various BiSbX layers may be the BiSb layer 310 of any of the SOT devices 300, 350, 400, 450 of FIGS. 3A-4B.

In the graph 500, line 502 represents undoped BiSb, line 504 represents BiSbCu, line 506 represents BiSbGe, line 508 represents BiSbN (doped with N₂), line 510 represents BiSbSi, line 512 represents BiSbGeN (deposited with Xe₂/N₁₀), line 514 represents BiSbGeN (deposited with Ar₄/N₁₆), line 516 represents BiSbCuN (deposited with Xe₂/N₁₀), and line 518 represents BiSbGeWN. However, it is noted that the various BiSbX films shown in the graph 500 are not limiting, and other options of X in BiSbX layers may be used as well, such as X=Si, C, Ru, Hf, Ni, Al, Y, Ti, Zr, Cr, Ir, V, Cu, Ag, Ge, Mn, Ni, Co, Mo, W, Sn, B, N, In, Te, Se, Pt, O, S, F, Cl, and Br, or in alloy combinations with one or more of aforementioned elements, like CuAg, CuNi, CoCu, AgSn, and Ge—TiO with 8 at. % of Sb (shown in FIG. 5B). The amount of dopant in each BiSbX layer may be less than about 8 at. %. Yet as shown in FIG. 5C, increasing Sb percentage can also increase the bulk conductivity by lowering the bandgap. The BiSbX layer may have a (012) crystal orientation or a (001) crystal orientation. The BiSbX layer may have a thickness in the y-direction of about 50 Å to about 600 Å.

As shown in the graph 500, at thin film thicknesses (e.g., less than or equal to about 15 nm), each line 502-522 has a similar high conductivity, such as greater than about 1.3×10⁵ ohm⁻¹m⁻¹, indicating there is a reduction in bulk conduction contribution, and all films show TI dominated surface conductivity. The tradeoff between surface conduction and bulk conductivity allows the tailoring of the in-plane Hall resistance or voltage, among other benefits. The bulk conductivity can be significantly increased by doping with an X-N dopant, examples shown in FIG. 5A are for Ge—N, Cu—N, and GeW—N dopants, Ge—TiO with 8 at. % of Sb in FIG. 5B, and increasing Sb percentage in FIG. 5C. Higher nitrogen containing X-N dopants can increase the bulk conduction even further, as in the case of Ge—N dopant of Xe2/N210 vs. Ar4/N16 and Ge—TiO with 8 at. % of Sb. These dopants reduce the surface conduction some but allow for increased manufacturability. These dopants not only increase the bulk conductivity, but have the added benefit of increasing the hardness, and melting point of the BiSbX alloy, allowing for reduced roughness and improved device reliability.

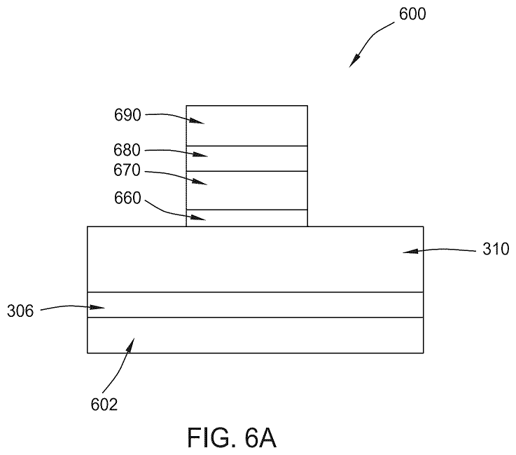

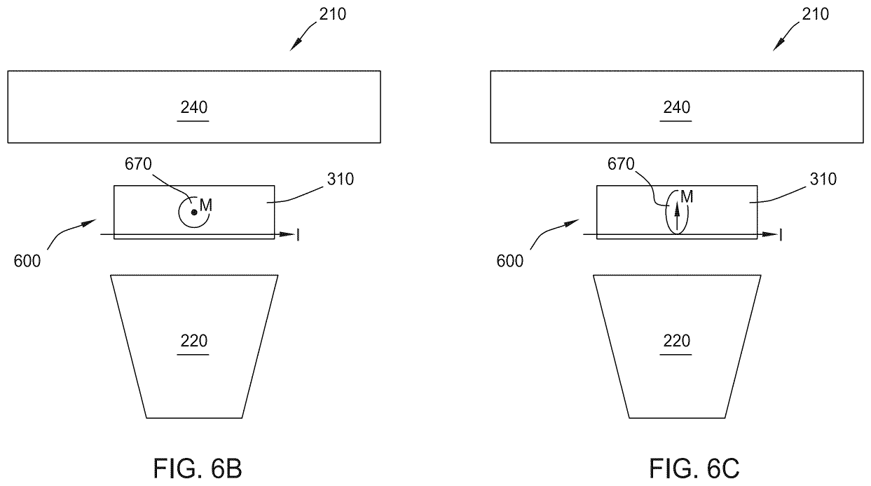

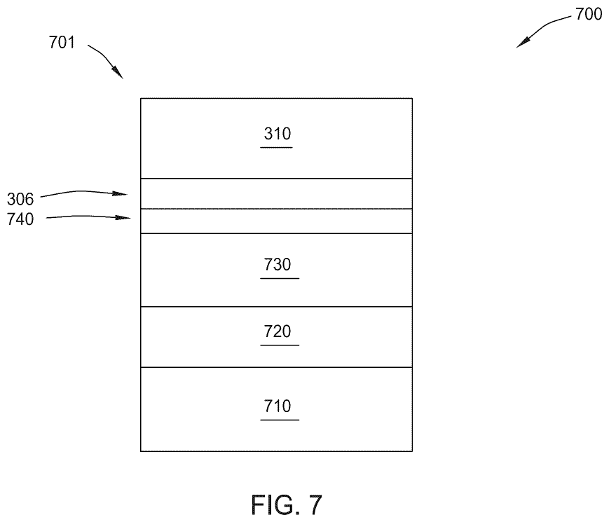

FIG. 6A is a schematic cross-sectional view of a CIP SOT device 600 for use in a MAMR write head, such as the MAMR write head of the drive 100 of FIG. 1 or other suitable magnetic media drives. The MAMR write head is based on a CIP SOT device. The CIP SOT device 600 comprises a BiSb layer 310 with a (012) orientation formed over a buffer layer 306 formed over a substrate 702, such as the BiSb layer 310 and the buffer layer 306 of FIGS. 3A-3B. A spin torque layer (STL) 670 is formed over the BiSb layer 310. The STL 670 comprises a ferromagnetic material such as one or more layers of CoFe, CoIr, NiFe, and CoFeX alloy wherein X=B, N, Ta, Re, or Ir.

In certain embodiments, an electrical current shunt block layer 660 is disposed between the BiSb layer 310 and the STL 670. The electrical current shunt blocking layer 660 reduces electrical current from flowing from the BiSb layer 310 to the STL 670 but allows spin orbital coupling of the BiSb layer 310 and the STL 670. In certain embodiments, the electrical current shunt blocking layer 660 comprises a magnetic material which provides greater spin orbital coupling between the BiSb layer 310 and the STL 670 than a non-magnetic material. In certain embodiments, the electrical current shunt blocking layer 660 comprises a magnetic material of FeCo, FeCOM, FeCOMO, FeCoMMeO, FeCOM/MeO stack, FeCoMNiMnMgZnFeO, FeCOM/NiMnMgZnFeO stack, multiple layers/stacks thereof, or combinations thereof in which M is one or more of B, Si, P, Al, Hf, Zr, Nb, Ti, Ta, Mo, Mg, Y, Cu, Cr, and Ni, and Me is Si, Al, Hf, Zr, Nb, Ti, Ta, Mg, Y, or Cr. In certain embodiments, the electrical current shunt blocking layer 660 is formed to a thickness from about 10 Å to about 100 Å. In certain aspects, an electrical current shunt blocking layer 660 having a thickness of over 100 Å may reduce spin orbital coupling of the BiSb layer 310 and the STL 670. In certain aspects, an electrical current shunt blocking layer having a thickness of less than 10 Å may not sufficiently reduce electrical current from BiSb layer 310 to the STL 670.

In certain embodiments, additional layers are formed over the STL 670 such as a spacer layer 680 and a pinning layer 690. The pinning layer 690 can partially pin the STL 670. The pinning layer 690 comprises a single or multiple layers of PtMn, NiMn, IrMn, IrMnCr, CrMnPt, FeMn, other antiferromagnetic materials, or combinations thereof. The spacer layer 780 comprises single or multiple layers of magnesium oxide, aluminum oxide, other non-magnetic materials, or combinations thereof.

FIGS. 6B-6C are schematic MFS views of certain embodiments of a portion of a MAMR write head 210 with a CIP SOT device 600 of FIG. 6A. The MAMR write head 210 can be the write head FIG. 2 or other suitable write heads in the drive 100 of FIG. 1 or other suitable magnetic media drives such as tape drives. The MAMR write head 210 is based on a CIP SOT device. The MAMR write head 210 includes a main pole 220 and a trailing shield 240 in a track direction. The CIP SOT device 600 is disposed in a gap between the main pole and the trailing shield 240.

During operation, charge current through a BiSb layer or layer stack 304 acting as a spin Hall layer generates a spin current in the BiSb layer. The spin orbital coupling of the BiSb layer and a spin torque layer (STL) 670 causes switching or precession of magnetization of the STL 670 by the spin orbital coupling of the spin current from the BiSb layer 310. Switching or precession of the magnetization of the STL 670 can generate an assisting AC field to the write field. Energy assisted write heads based on SOT have multiple times greater power efficiency in comparison to MAMR write heads based on spin transfer torque. As shown in FIG. 6B, an easy axis of a magnetization direction of the STL 670 is perpendicular to the MFS from shape anisotropy of the STL 670, from the pinning layer 690 of FIG. 6A, and/or from hard bias elements proximate the STL 670. As shown in FIG. 6C, an easy axis of a magnetization direction of the STL 670 is parallel to the MFS from shape anisotropy of the STL 670, from the pinning layer 690 of FIG. 6A, and/or from hard bias elements proximate the STL 670.

FIG. 7 is a schematic cross-sectional view of a CIP SOT MTJ 701 used as a MRAM device 700. The MRAM device 700 is based on a CIP SOT device. The MRAM device 700 comprises a reference layer (RL) 710, a spacer layer 720 over the RL 710, a recording layer 730 over the spacer layer 720, a buffer layer 306 over an electrical current shunt block layer 740 over the recording layer 730, and a BiSb layer or layer stack 310 over the buffer layer 306. The BiSb layer 310 and the buffer layer 306 may be the BiSb layer 304 and the buffer layer 310 of FIGS. 3A-3B.

The RL 710 comprises single or multiple layers of CoFe, other ferromagnetic materials, and combinations thereof. The spacer layer 720 comprises single or multiple layers of magnesium oxide, aluminum oxide, other dielectric materials, or combinations thereof. The recording layer 730 comprises single or multiple layers of CoFe, NiFe, other ferromagnetic materials, or combinations thereof.

As noted above, in certain embodiments, the electrical current shunt block layer 740 is disposed between the buffer layer 306 and the recording layer 730. The electrical current shunt blocking layer 740 reduces electrical current from flowing from the BiSb layer 310 to the recording layer 730 but allows spin orbital coupling of the BiSb layer 310 and the recording layer 730. For example, writing to the MRAM device can be enabled by the spin orbital coupling of the BiSb layer and the recording layer 730, which enables switching of magnetization of the recording layer 730 by the spin orbital coupling of the spin current from the BiSb layer 310. In certain embodiments, the electrical current shunt blocking layer 740 comprises a magnetic material which provides greater spin orbital coupling between the BiSb layer 310 and the recording layer 730 than a non-magnetic material. In certain embodiments, the electrical current shunt blocking layer 740 comprises a magnetic material of FeCOM, FeCOMO, FeCoMMeO, FeCOM/MeO stack, FeCoMNiMnMgZnFeO, FeCOM/NiMnMgZnFeO stack, multiple layers/stacks thereof, or combinations thereof, in which M is one or more of B, Si, P, Al, Hf, Zr, Nb, Ti, Ta, Mo, Mg, Y, Cu, Cr, and Ni, and Me is Si, Al, Hf, Zr, Nb, Ti, Ta, Mg, Y, or Cr.

The MRAM device 700 of FIG. 7 may include other layers, such as pinning layers, pinning structures (e.g., a synthetic antiferromagnetic (SAF) pinned structure), electrodes, gates, and other structures. Other MRAM devices besides the structure of FIG. 7 can be formed utilizing a BiSb layer 310 with a (012) orientation over a buffer layer 306 to form a SOT MTJ 701.

Therefore, by selecting a thickness and a dopant of a BiSb or YBiPt layer during fabrication of a CIP SOT device, its bandgap can be decreased to improve to increase the conductivity of the CIP SOT device for lower power consumption.

In one embodiment, a current-in-plane (CIP) spin orbit torque (SOT) device comprises a buffer layer, a doped bismuth antimony (BiSb) layer over the buffer layer, the doped BiSb layer comprising BiSb and a Ge—TiO, Ge-VO, or X-N dopant for controlling a bandgap of the BiSb layer, wherein the X-N dopant comprises N and X is one or more of elements selected from the group consisting of: Sc, Ti, V, Cr, Zr, Nb, Mo, Hf, Ta, W, Cu, Rh, Ir, Pd, Pt, B, Al, Ga, In, Si, Ge, Sn, As, S, Se, Te, and alloy combinations thereof, an interlayer over the BiSb layer, and a ferromagnetic layer over the interlayer.

The amount of dopant between 0.1 at. % to about 8 at. %, and wherein a thickness of the doped BiSb layer is between about 50 Å to about 600 Å. One or more of the buffer layer, the interlayer, and the ferromagnetic layer is also doped with the dopant. The doped BiSb layer has an amount of conductivity of about 1.5×10⁵ ohm⁻¹m⁻¹ or above. The doped BiSb layer comprises BiSb and the X-N dopant, wherein the X-N dopant comprises N and X is selected from the group consisting of: Sc, Ti, V, Cr, Zr, Nb, Mo, Hf, Ta, W, and alloy combinations thereof. The doped BiSb layer comprises BiSb and the X-N dopant, wherein the X-N dopant comprises N and X is selected from the group consisting of: Cu, Pd, Al, Si, Ge, and alloy combinations thereof. A magnetic recording device comprises the CIP SOT. A magnetoresistive random access memory device comprising the CIP SOT device. A logic device comprising the CIP SOT device.

In another embodiment, a current-in-plane (CIP) spin orbit torque (SOT) device comprises a buffer layer, a doped yttrium bismuth platinum (YBiPt) layer over the buffer layer, the doped YBiPt layer comprising YBiPt and a X-N dopant, a X-C dopant, or a X-O dopant, where X is one or more of elements selected from the group consisting of: Sc, Ti, V, Cr, Zr, Nb, Mo, Hf, Ta, W, Cu, Rh, Ir, Pd, Pt, B, Al, Ga, In, Si, Ge, Sn, As, S, Se, Te, Ge—Ti, and alloy combinations thereof, an interlayer over the BiSb layer, and a ferromagnetic layer over the interlayer.

The amount of C dopant between 0.1 at. % to about 8 at. %, and wherein a thickness of the doped YBiPt layer is between about 50 Å to about 600 Å. One or more of the buffer layer, the interlayer, and the ferromagnetic layer is also doped with the X-N dopant, the X-C dopant, or the X-O dopant. A magnetic recording device comprises the CIP SOT. A magnetoresistive random access memory device comprising the CIP SOT device. A logic device comprising the CIP SOT device.

In yet another embodiment, a current-in-plane (CIP) spin orbit torque (SOT) device comprises a buffer layer, a doped bismuth antimony (BiSb) layer over the buffer layer, the doped BiSb layer comprising BiSb and a dopant for controlling a bandgap of the BiSb layer, wherein the dopant is one or more of elements selected from the group consisting of: B, Al, Ga, In, N, C, Si, Ge, Sn, P, As, Ni, Cu, Zn, Mg, Zr, Nb, Mo, Ta, Hf, W, Pt, Ir, Ge—TiO, GeN, GeWN, and alloy dopant combinations thereof, an interlayer over the BiSb layer, and a ferromagnetic layer over the interlayer.

The amount of dopant between 0.1 at. % to about 8 at. %, and wherein a thickness of the doped BiSb layer is between about 50 Å to about 600 Å. One or more of the buffer layer, the interlayer, and the ferromagnetic layer is also doped with the dopant. The doped BiSb layer has an amount of conductivity of about 1.5×10⁵ ohm⁻¹m⁻¹ or above. A magnetic recording device comprises the CIP SOT. A magnetoresistive random access memory device comprising the CIP SOT device. A logic device comprising the CIP SOT device.

While the foregoing is directed to embodiments of the present disclosure, other and further embodiments of the disclosure may be devised without departing from the basic scope thereof, and the scope thereof is determined by the claims that follow.

What is claimed is:

1. A current-in-plane (CIP) spin orbit torque (SOT) device, comprising:
a buffer layer;
a doped bismuth antimony (BiSb) layer over the buffer layer, the doped BiSb layer comprising BiSb and a Ge—TiO, Ge-VO, or X-N dopant for controlling a bandgap of the BiSb layer, wherein the X-N dopant comprises N and X is one or more elements selected from the group consisting of: Sc, Ti, V, Cr, Zr, Nb, Mo, Hf, Ta, W, Cu, Rh, Ir, Pd, Pt, B, Al, Ga, In, Si, Ge, Sn, As, S, Se, Te, and alloy combinations thereof;
an interlayer over the BiSb layer; and
a ferromagnetic layer over the interlayer.

2. The CIP SOT device of claim 1, wherein the amount of dopant between 0.1 at. % to about 8 at. %, and wherein a thickness of the doped BiSb layer is between about 50 Å to about 600 Å.

3. The CIP SOT device of claim 1, wherein one or more of the buffer layer, the interlayer, and the ferromagnetic layer is also doped with the dopant.

4. The CIP SOT device of claim 1, wherein the doped BiSb layer has an amount of conductivity of about 1.5×10⁵ ohm⁻¹m⁻¹ or above.

5. The CIP SOT device of claim 1, wherein the doped BiSb layer comprises BiSb and the X-N dopant, wherein the X-N dopant comprises N and X is selected from the group consisting of: Sc, Ti, V, Cr, Zr, Nb, Mo, Hf, Ta, W, and alloy combinations thereof.

6. The CIP SOT device of claim 1, wherein the doped BiSb layer comprises BiSb and the X-N dopant, wherein the X-N dopant comprises N and X is selected from the group consisting of: Cu, Pd, Al, Si, Ge, and alloy combinations thereof.

7. A magnetic recording device comprising the CIP SOT device of claim 1.

8. A magnetoresistive random access memory device comprising the CIP SOT device of claim 1.

9. A logic device comprising the CIP SOT device of claim 1.

10. A current-in-plane (CIP) spin orbit torque (SOT) device, comprising:
a buffer layer;
a doped yttrium bismuth platinum (YBiPt) layer over the buffer layer, the doped YBiPt layer comprising YBiPt and a X-N dopant, a X-C dopant, or a X-O dopant, where X is one or more elements selected from the group consisting of: Sc, Ti, V, Cr, Zr, Nb, Mo, Hf, Ta, W, Cu, Rh, Ir, Pd, Pt, B, Al, Ga, In, Si, Ge, Sn, As, S, Se, Te, Ge—Ti, and alloy combinations thereof;
an interlayer over the YBiPt layer; and
a ferromagnetic layer over the interlayer.

11. The CIP SOT device of claim 10, wherein the amount of C dopant between 0.1 at. % to about 8 at. %, and wherein a thickness of the doped YBiPt layer is between about 50 Å to about 600 Å.

12. The CIP SOT device of claim 10, wherein one or more of the buffer layer, the interlayer, and the ferromagnetic layer is also doped with the X-N dopant, the X-C dopant, or the X-O dopant.

13. A magnetic recording device comprising the CIP SOT device of claim 10.

14. A magnetoresistive random access memory device comprising the CIP SOT device of claim 10.

15. A logic device comprising the CIP SOT device of claim 10.

16. A current-in-plane (CIP) spin orbit torque (SOT) device, comprising:
a buffer layer;
a doped bismuth antimony (BiSb) layer over the buffer layer, the doped BiSb layer comprising BiSb and a dopant for controlling a bandgap of the BiSb layer, wherein the dopant is one or more of elements selected from the group consisting of: B, Al, Ga, In, N, C, Si, Ge, Sn, P, As, Ni, Cu, Zn, Mg, Zr, Nb, Mo, Ta, Hf, W, Pt, Ir, Ge—TiO, GeN, GeWN, Ge-VO, and alloy dopant combinations thereof;
an interlayer over the BiSb layer; and
a ferromagnetic layer over the interlayer.

17. The CIP SOT device of claim 16, wherein the amount of dopant between 0.1 at. % to about 8 at. %, and wherein a thickness of the doped BiSb layer is between about 50 Å to about 600 Å.

18. The CIP SOT device of claim 16, wherein one or more of the buffer layer, the interlayer, and the ferromagnetic layer is also doped with the dopant.

19. The CIP SOT device of claim 16, wherein the doped BiSb layer has an amount of conductivity of about 1.5×10⁵ ohm⁻¹m⁻¹ or above.

20. A magnetic recording device comprising the CIP SOT device of claim 16.

21. A magnetoresistive random access memory device comprising the CIP SOT device of claim 16.

22. A logic device comprising the CIP SOT device of claim 16.
